(19) United States
(12) Patent Application Publication
(10) Pub. No.: US 2007/0075780 A1
(43) Pub. Date: Apr. 5, 2007

(54) Apparatus and method for adaptive biasing of a Doherty amplifier

(76) Inventors: Enver Krvavac, Lake Zurich, IL (US); Joseph G. Schultz, Wheaton, IL (US); Yinglei Yu, Tempe, AZ (US)

Correspondence Address: MOTOROLA, INC., 1303 EAST ALGONQUIN ROAD, IL01/3RD, SCHAUMBURG, IL, 60196, US

(21) Appl. No.: 11/215,661

(22) Filed: Oct. 5, 2005

(51) Int. Cl. H03F 3/68

(52) U.S. Cl. 330/295

(57) ABSTRACT

An apparatus and method for adaptive biasing of a Doherty amplifier (102) is disclosed. The apparatus includes a carrier amplifier (210), a peaking amplifier (214), a carrier amplifier bias circuit (208) and a peaking amplifier bias circuit (212), all integrated onto a single chip. The method includes dividing an input signal into an in-phase signal and a quadrature phase signal. The method further includes sampling the input signal and applying the sampled signal to the biasing circuits. The method further includes adaptively biasing the carrier amplifier and the peaking amplifier by the output of the biasing circuits.

### FIELD OF THE INVENTION

This invention relates in general to Doherty amplifiers, and more specifically, to adaptive biasing of Doherty amplifiers.

### BACKGROUND OF THE INVENTION

A power amplifier should be able to linearly amplify Radio Frequency (RF) signals in an efficient manner. However, there is always some kind of tradeoff between efficiency and linearity. A type of power amplifier, called a Doherty amplifier, is more efficient than standard class AB and class B amplifiers. This advantage can be attributed to the load line of a carrier amplifier in a Doherty amplifier, which can be modulated instantaneously as the RF input level changes. In other words, Doherty amplifiers have a better tradeoff between maximum efficiency and high linearity because the amplifier's load line is continuously modified to maintain high efficiency as input drive levels change. Therefore, in order to achieve high efficiency linearity, the load line of a Doherty amplifier has to be dynamically modified with a change in the input. In other words, a Doherty amplifier should be adaptively biased.

A known method to adaptively bias a Doherty amplifier relies on changes in the gate or source bias current of the carrier amplifier as a way of measuring the RF input power to that device. Such a method is not effective in the case of metal oxide semiconductor field effect transistor (MOSFET) amplifier devices because such devices do not draw bias current at any RF drive level.

Another known method describes adaptive biasing based on changes in the input signal. However the adaptive biasing circuit is external to the chip on which the power amplifier is mounted and is too complex to be implemented on a chip. This makes the adaptive biasing slow to respond to the changes in the input signal. Moreover the adaptive biasing circuit does not perform adaptive biasing of the amplifier based on a change in an operating temperature of the amplifier.

Therefore a need exists for an adaptive bias circuit that is simple enough to be mounted on a same chip as a corresponding Doherty amplifier and that will perform adaptive biasing of the amplifier based on the input RF drive level.

### BRIEF DESCRIPTION OF THE DRAWINGS

The present invention is illustrated by way of example and not limitation in the accompanying figures, in which like references indicate similar elements, and in which:

FIG. 1 is a block diagram of a Doherty amplifier in accordance with an embodiment of the invention.

FIG. 2 is a block diagram of a Doherty amplifier with a bias control circuit in accordance with an embodiment of the invention.

FIG. 3 is an exemplary block diagram of a carrier amplifier bias circuit in accordance with an embodiment of the invention.

FIG. 4 is a block diagram of a peaking amplifier bias circuit in accordance with an embodiment of the invention.

FIG. 5 is a logic flow diagram illustrating a method for adaptive biasing of a Doherty amplifier in accordance with an embodiment of the invention.

FIG. 6 is a continuation of the logic flow diagram of FIG. 5 illustrating a method for adaptive biasing of a Doherty amplifier in accordance with an embodiment of the invention.

FIG. 7 is an exemplary graphical representation of a change in the gate bias of a carrier amplifier with respect to a change in an input signal, in accordance with an embodiment of the invention.

FIG. 8 is an exemplary graphical representation of a change in the gate bias of a peaking amplifier with respect to a change in an input signal, in accordance with an embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

Elements in the Figures are illustrated for simplicity and clarity and have not necessarily been drawn to scale. For example, the dimensions of some of the elements in the Figures may be exaggerated relative to other elements to help improve understanding of various embodiments of the present invention. Furthermore, the terms “first”, “second”, and the like herein, if any, are used inter alia for distinguishing between similar elements and not necessarily for describing a sequential or chronological order. Any of the preceding terms so used may be interchanged under appropriate circumstances such that various embodiments of the invention described herein may be capable of operation in other configurations and/or orientations than those explicitly illustrated or otherwise described.

### DETAILED DESCRIPTION OF THE EMBODIMENTS

Before describing in detail the particular apparatus and method for adaptive biasing of a Doherty amplifier in accordance with the present invention, it should be observed that the present invention resides primarily in combinations of method steps and apparatus components related to apparatus and method for adaptive biasing of a Doherty amplifier. Accordingly, the apparatus components and method steps have been represented where appropriate by conventional symbols in the drawings, showing only those specific details that are pertinent to understanding the present invention so as not to obscure the disclosure with details that will be readily apparent to those of ordinary skill in the art having the benefit of the description herein.

The invention describes an apparatus and method for adaptive biasing of an on-chip integrated LDMOS Doherty amplifier. The Doherty amplifier includes a carrier amplifier to amplify an in-phase signal and a peaking amplifier to amplify a quadrature phase signal. Different bias signals are provided to the carrier amplifier and the peaking amplifier by a carrier amplifier bias circuit and a peaking amplifier bias circuit respectively. The carrier amplifier bias circuit, which acts as a rectifying amplifier, is coupled to the carrier amplifier. Similarly, the peaking amplifier bias circuit, which acts as a difference amplifier, is coupled to the peaking amplifier and to the output of the carrier amplifier bias circuit. The carrier amplifier, the peaking amplifier, the carrier amplifier bias circuit and the peaking amplifier bias circuit are all integrated onto a single chip.

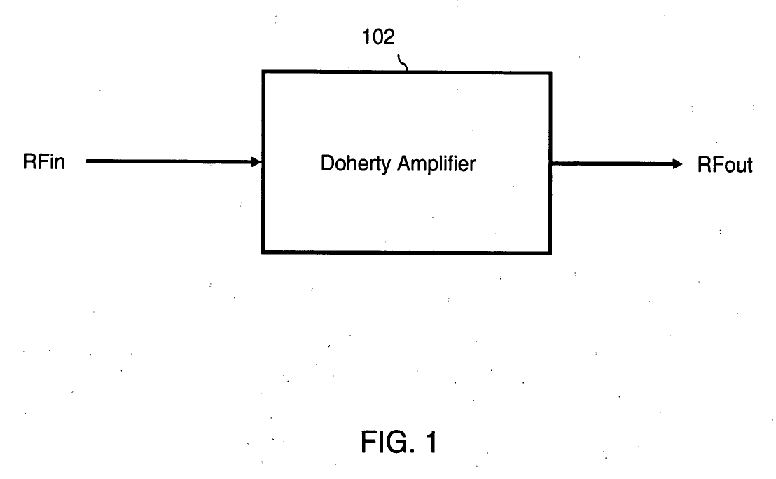

FIG. 1 depicts an exemplary Doherty amplifier 102, in accordance with an embodiment of the invention. The Doherty amplifier 102 accepts a Radio Frequency (RF) signal, RFin, as input. It then amplifies this signal and provides an amplified RF signal, RFout, as output.

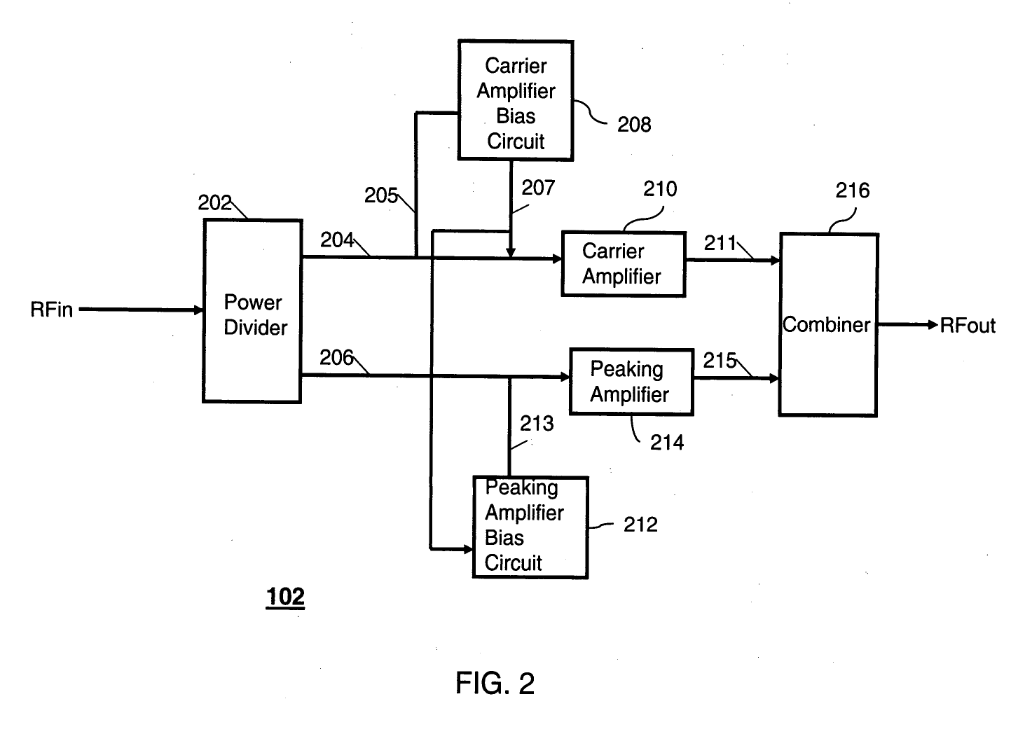

FIG. 2 is an exemplary block diagram of the Doherty amplifier 102 with bias control in accordance with an embodiment of the invention. The RF input signal RFin is provided as input to a power divider 202, which divides the RF input signal into an in-phase signal 204 and a quadrature phase signal 206. The in-phase signal 204 has no phase difference with respect to the RF input signal, whereas the quadrature phase signal 206 lags in phase with respect to the RF input signal by 90 degree. Power divider 202 provides the in-phase signal 204 as input to a carrier amplifier 210. In-phase signal 204 is further sampled to produce a sampled in-phase signal 205 that is provided to a carrier amplifier bias circuit 208 coupled to an input of the carrier amplifier. Power divider 202 provides the quadrature phase signal 206 as input to a peaking amplifier 214. The carrier amplifier bias circuit 208 is further coupled to the peaking amplifier bias circuit 212. Each of the carrier amplifier 210 and the peaking amplifier 212 comprises a field effect transistor (FET) that amplifies an RF signal applied to the FET to produce an amplified RF signal.

Based on the sampled in-phase signal 205, carrier amplifier bias circuit 208 produces a carrier amplifier bias input 207 comprising a carrier amplifier bias voltage that is applied to a gate terminal of the FET of the carrier amplifier 210 and further is applied to the peaking amplifier bias circuit 212. Based on the carrier amplifier bias voltage, peaking amplifier bias circuit 212 produces a peaking amplifier bias input 213 comprising a peaking amplifier bias voltage that is applied to a gate terminal of the FET of the peaking amplifier 214. The carrier amplifier 210, more particularly the FET of the carrier amplifier, amplifies the in-phase signal 204 based on the carrier amplifier bias input 207 to produce a first output signal 211. Similarly, the peaking amplifier 214, more particularly the FET of the peaking amplifier, amplifies the quadrature phase signal 206 based on the peaking amplifier bias input 213 to produce a second amplified signal 215. The first output signal 211 is applied as input to a combiner 216 as a first signal. The second output signal 215 is applied as input to the combiner 216 as a second signal. The combiner 216 combines the first signal 211 and the second signal 215 in phase to provide the output signal RFout.

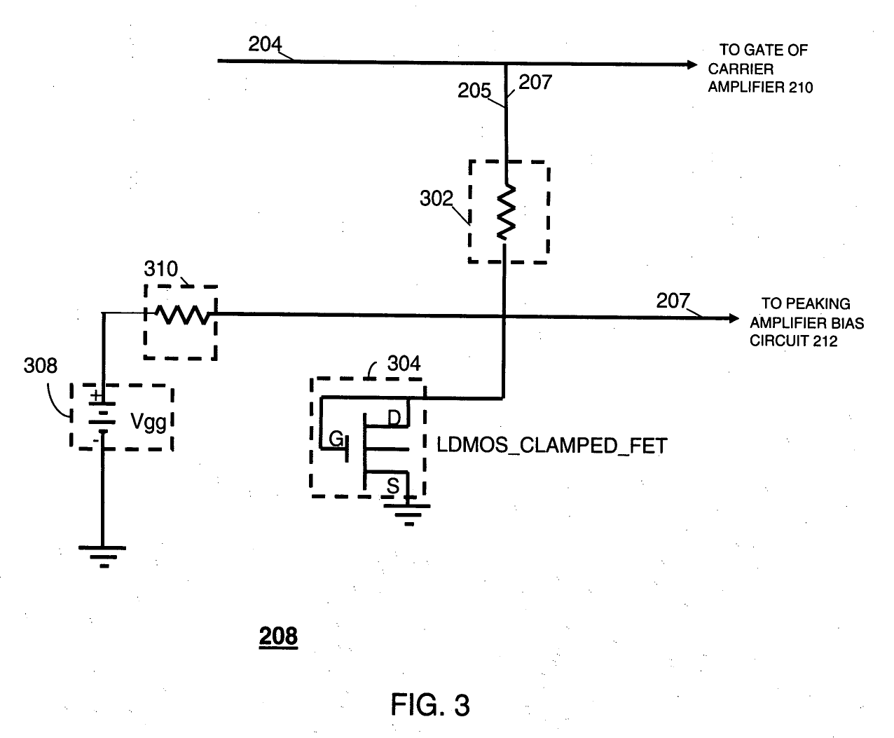

FIG. 3 is an exemplary block diagram of the carrier amplifier bias circuit 208 in accordance with an embodiment of the invention. The carrier amplifier bias circuit 208 acts as a rectifying amplifier, and is coupled to the carrier amplifier 210. The carrier amplifier bias circuit 208 includes a first resistor 302 and a clamped FET 304, which are mounted on a chip along with the carrier amplifier 210. The resistor 302 couples the gate terminal of the FET of the carrier amplifier 210 to the gate terminal of the clamped FET 304. In an embodiment of the invention the resistor 302 is a 150 ohms resistor. The clamped FET 304 has its drain and gate terminals clamped. In an embodiment of the invention, the clamped FET 304 is a lateral drain metal oxide semiconductor (LDMOS) and acts as a rectifying amplifier. In an embodiment of the invention the carrier amplifier 210 and the clamped FET 304 are identical field effect transistors. This leads to the FET of the carrier amplifier 210 and the clamped FET 304 sharing a similar process, temperature, and history profile. The in-phase signal 204, which is an output of the power divider 202, is coupled to the carrier amplifier 210. The clamped FET 304 is connected to an external voltage Vgg 308 via a second, external resistor 310. In an embodiment of the invention, the value of the external resistor 310 is 330 ohms.

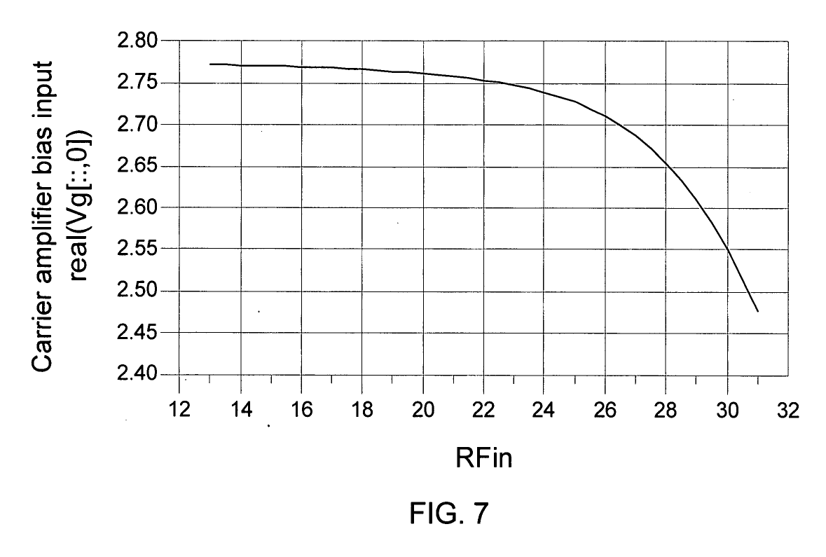

The operation of the rectifying amplifier is as follows. The clamped FET 304 operates in a feedback environment. The external voltage Vgg 308 and the external resistor 310 set up a reference current for the clamped FET 304, which set the initial bias voltage to the radio frequency (RF) FET of the carrier amplifier 210. The clamped FET 304 rectifies the in-phase signal, sampled through resistor 302, which produces a DC (Direct Current) current through the FET 304 and thereby provides the carrier amplifier bias input 207. An increase in the magnitude of the RF input signal corresponds to an increase in the magnitude of the in-phase signal 204, resulting in an increase in the amount of rectification by the clamped FET 304 and thus increase in DC current through the FET 304. Hence an increase in the magnitude of the RF input signal corresponds to a decrease in the carrier amplifier bias voltage. Conversely, a decrease in the magnitude of the RF input signal corresponds to a decrease in the magnitude of the in-phase signal 204, resulting in a decrease in the amount of rectification by the clamped FET 304. Hence a decrease in the magnitude of the RF input signal corresponds to an increase in the carrier amplifier bias voltage. FIG. 7 depicts the adaptive carrier amplifier bias voltage.

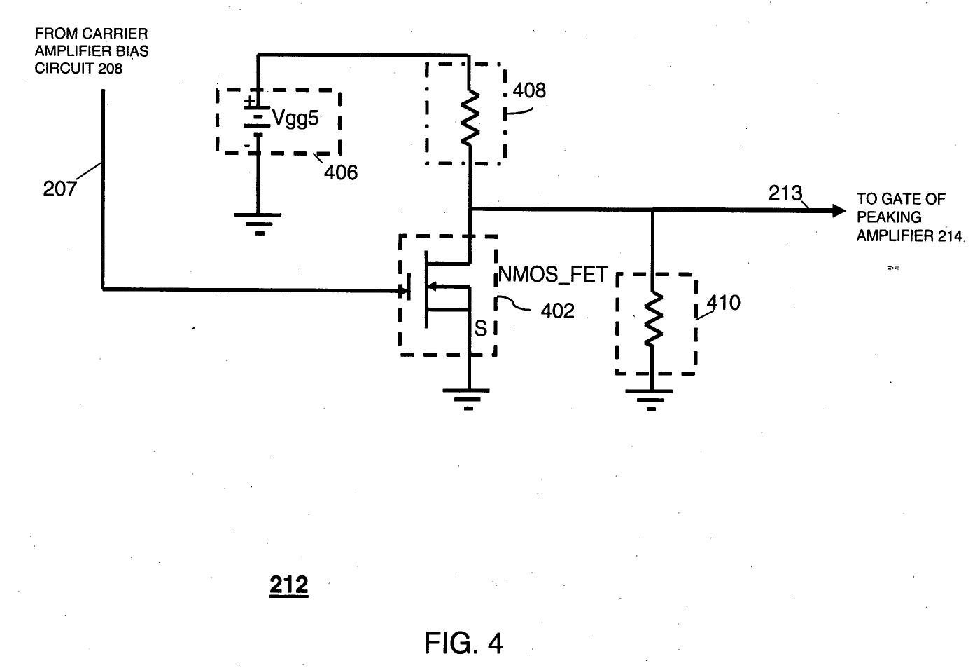

FIG. 4 is an exemplary block diagram of a peaking amplifier bias circuit 212 in accordance with an embodiment of the invention. The peaking amplifier bias circuit 212 includes a difference amplifier 402. In an embodiment of the invention, the difference amplifier 402 is a negative channel metal oxide semiconductor (NMOS), which can be realized in a lateral drain metal oxide semiconductor process. The difference amplifier 402 is coupled to an external voltage Vgg5 406 through a third resistor 408. An output of the carrier amplifier bias circuit, that is, the adaptive carrier amplifier bias voltage 207, is coupled to a gate of the difference amplifier 402. A fourth resistor 410 is connected to the drain terminal of the difference amplifier 402, which acts as the load to the difference amplifier.

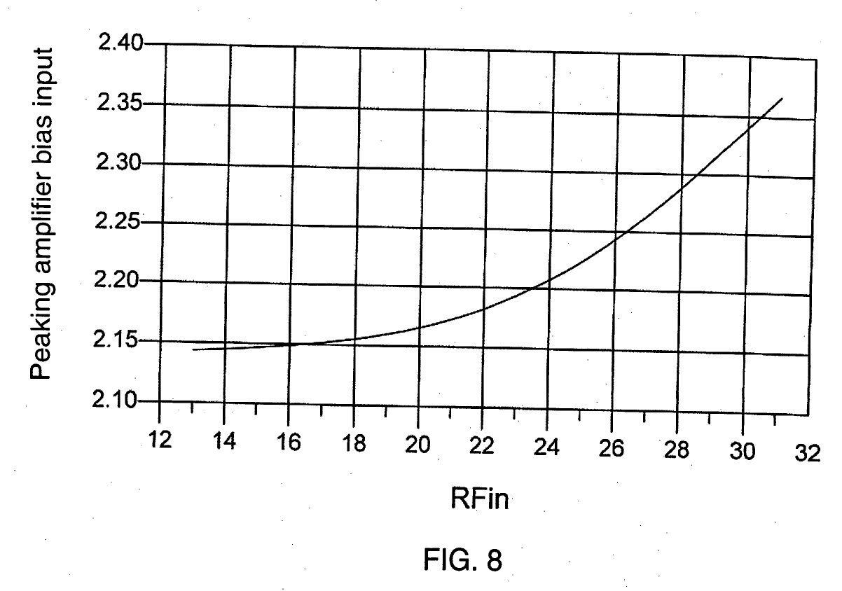

The operation of the difference amplifier is as follows. The difference amplifier 402 is coupled to the output of the carrier amplifier bias circuit. The difference amplifier 402 subtracts the carrier amplifier bias voltage from a fixed external voltage Vgg5 406 to produce the adaptive peaking amplifier bias input 213 that is applied to the gate of the FET of the peaking amplifier 214. This ensures an increasing gate bias voltage to the peaking amplifier 214 when the gate bias voltage of the carrier amplifier 210 is decreasing. An increase in the magnitude of the RF input signal corresponds to an increase in the peaking amplifier bias input. Conversely, a decrease in the magnitude of the RF input signal corresponds to a decrease in the peaking amplifier bias input. FIG. 8 depicts the adaptive peaking amplifier bias voltage.

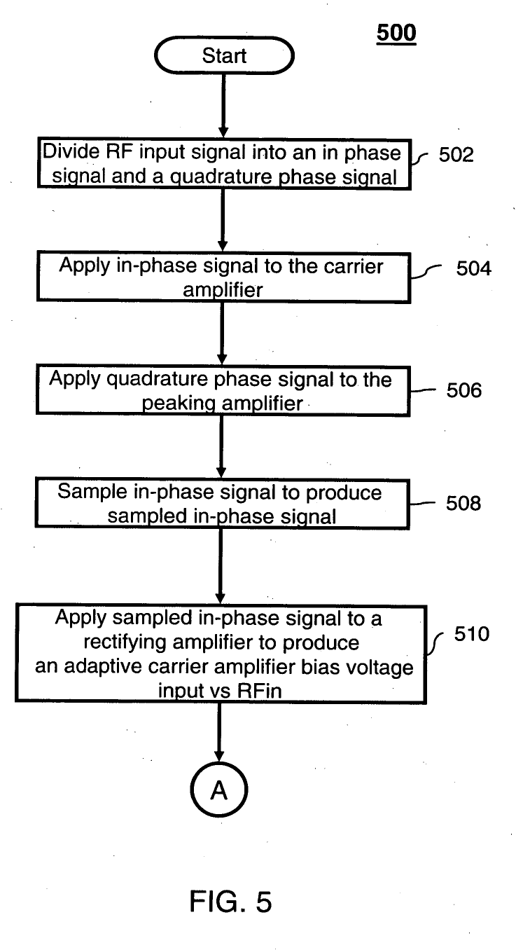

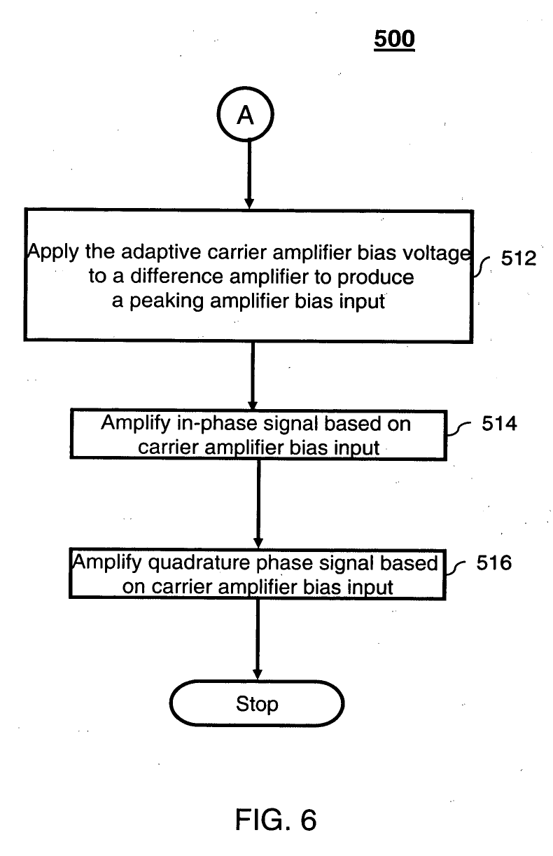

Referring now to FIGS. 5 and 6, a logic flow diagram 500 is provided that illustrates a method for adaptive biasing of the Doherty amplifier 102 in accordance with an embodiment of the invention. At step 502, the power divider 202 divides an RF input signal into an in-phase signal and a quadrature phase signal. The in-phase signal has no phase difference with respect to the RF input signal, whereas the quadrature phase signal lags the RF input signal by 90 degrees. At step 504, the in-phase signal is applied to the carrier amplifier 210. Similarly at step 506, the quadrature phase signal is applied to the peaking amplifier 214. At step 508, the in-phase signal is sampled by coupling the in-phase signal to the carrier amplifier bias circuit 208 to produce a sampled in-phase signal. At step 510, a carrier amplifier bias input comprising a carrier amplifier bias voltage is produced by applying the sampled in phase signal to the carrier amplifier bias circuit 208 which acts as a rectifying amplifier. At step 512, a peaking amplifier bias input is produced by applying the carrier amplifier bias voltage, outputted by the carrier amplifier circuit, to the peaking amplifier bias circuit 212, which acts as a difference amplifier. The in-phase and the quadrature phase signals are sampled in order to determine the magnitude of the in-phase signal and the quadrature phase signal respectively. By determining the magnitude of the in-phase signal and the quadrature phase signal the magnitude of the RF input signal is known. Since the in-phase signal and the quadrature phase signal are derived from a common source, which is the RF input signal, the magnitude of the sampled in-phase signal and the sampled quadrature phase signal will be inter-related.

At step 514, the in-phase signal is amplified by the carrier amplifier 210 on the basis of the carrier amplifier bias input. Similarly, at step 516, the quadrature phase signal is amplified by the peaking amplifier 214 on the basis of the peaking amplifier bias input.

FIG. 7 is an exemplary graphical representation of a change in the carrier amplifier bias input with respect to a change in the RF input signal in accordance with an embodiment of the invention. As described earlier, the graph shows that the carrier amplifier bias input decreases with an increase in the RF input signal.

FIG. 8 is an exemplary graphical representation of a change in the peaking amplifier bias input with respect to a change in the RF input signal in accordance with an embodiment of the invention. As described earlier, the graph shows that the peaking amplifier bias input increases with an increase in the RF input signal

In summarization, an apparatus and a method is provided for adaptive biasing of a Doherty amplifier that is sufficiently simple that the biasing components may be integrated onto the same chip as the Doherty amplifier. This does away with the need for external circuitry for biasing of the Doherty amplifier and further, by placing the biasing circuitry on the same chip as the Doherty amplifier, allows the FETs of the carrier and peaking amplifier bias circuits to operate under similar temperature conditions as the FETs of the carrier and peaking amplifiers. By matching the operating temperature conditions of the bias circuits with the amplifiers that they are providing a bias input to, the Doherty amplifier is capable of temperature tracking and self-biasing of both the carrier and peaking amplifiers. In addition, the Doherty amplifier displays an improved peak power capability over earlier Doherty amplifiers. The present invention also improves the efficiency-linearity tradeoff.

In this document, relational terms such as first and second, and the like may be used solely to distinguish one entity or action from another entity or action without necessarily requiring or implying any actual such relationship or order between such entities or actions. The terms “comprises,” “comprising”, “includes”, “including” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

In the foregoing specification, the invention and its benefits and advantages have been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A Doherty amplifier comprising:
a carrier amplifier for amplifying an in-phase signal, wherein the carrier amplifier is provided with a carrier amplifier bias input;
a peaking amplifier for amplifying a quadrature phase signal, wherein the peaking amplifier is provided with a peaking amplifier bias input;
a carrier amplifier bias circuit coupled to the carrier amplifier, wherein the carrier amplifier bias circuit comprises a rectifying amplifier and provides the carrier amplifier bias input; and
a peaking amplifier bias circuit coupled to the peaking amplifier, wherein the peaking amplifier bias circuit comprises a difference amplifier and provides the peaking amplifier bias input;
wherein the carrier amplifier bias circuit and the peaking amplifier bias circuit are coupled to a radio frequency (RF) input signal, and wherein the carrier amplifier, the peaking amplifier, the carrier amplifier bias circuit and the peaking amplifier bias circuit are integrated on a single chip.

2. The Doherty amplifier in accordance with claim 1, wherein the rectifying amplifier comprises a clamped field effect transistor.

3. The Doherty amplifier in accordance with claim 2, wherein the carrier amplifier and the clamped field effect transistor each comprises a lateral drain metal oxide semiconductor.

4. The Doherty amplifier in accordance with claim 1, wherein the difference amplifier comprises a field effect transistor.

5. The Doherty amplifier in accordance with claim 4, wherein the difference amplifier comprises a negative channel metal oxide semiconductor.

6. The Doherty amplifier in accordance with claim 1 further comprising a power divider coupled to the RF input signal for producing the in-phase signal and the quadrature phase signal from the RF input signal.

7. The Doherty amplifier in accordance with claim 1 further comprising a combiner coupled to an output of the carrier amplifier and an output of the peaking amplifier, the combiner combining the output of the carrier amplifier and the output of the peaking amplifier in additive phase.

8. The Doherty amplifier in accordance with claim 1, wherein the carrier amplifier and the rectifying amplifier have similar temperature profiles.

9. A method for adaptive biasing of a Doherty amplifier, the method comprising:
dividing a radio frequency input signal into an in-phase signal and a quadrature phase signal;
applying the in-phase signal to a carrier amplifier;
applying the quadrature phase signal to a peaking amplifier;
sampling the in-phase signal to produce a sampled in-phase signal;
applying the sampled in-phase signal to a rectifying amplifier to produce a carrier amplifier adaptive bias input;
applying the carrier amplifier adaptive bias voltage to a difference amplifier to produce a peaking amplifier bias input;
amplifying the in-phase signal based on the carrier amplifier bias input to produce a first amplified signal; and
amplifying the quadrature phase signal based on the peaking amplifier bias input to produce a second amplified signal.

10. The method of claim 9, further comprising combining the first amplified signal with the second amplified signal to produce an output signal, wherein the first amplified signal and the second amplified signal are combined in phase.

11. The method of claim 9, wherein sampling the in-phase signal comprises coupling the in-phase signal to a carrier amplifier bias circuit and the output of the circuit is couple to a peaking amplifier bias circuit.

12. The method of claim 9, further comprising:
decreasing the carrier amplifier bias input upon increase of the radio frequency input signal; and
increasing the peaking amplifier bias input upon increase of the radio frequency input signal.
